(19) United States
(12) Patent Application Publication
(10) Pub. No.: US 2024/0299981 A1
(43) Pub. Date: Sep. 12, 2024

(54) ULTRASONIC TRANSDUCER AND METHOD OF MANUFACTURING THE SAME

(71) Applicant: Murata Manufacturing Co., Ltd., Nagaokakyo-shi (JP)

(72) Inventors: Kenji KORESAWA, Nagaokakyo-shi (JP); Yusuke SUZUKI, Nagaokakyo-shi (JP); Junichi NOMURA, Nagaokakyo-shi (JP); Tomoaki MATSUSHITA, Nagaokakyo-shi (JP); Akio FUJITA, Nagaokakyo-shi (JP); Kazuhiko FUJII, Nagaokakyo-shi (JP)

(21) Appl. No.: 18/666,873

(22) Filed: May 17, 2024

Related U.S. Application Data
(63) Continuation of application No. PCT/JP2022/037055, filed on Oct. 4, 2022.

(30) Foreign Application Priority Data
Nov. 29, 2021 (JP) 2021-193286

(51) Int. Cl. B06B 1/06; H10N 30/06; H10N 30/853; H10N 30/87; H10N 30/88

(52) U.S. Cl. CPC B06B 1/0644; H10N 30/06; H10N 30/8554; H10N 30/875; H10N 30/88

(57) ABSTRACT

A case, a piezoelectric vibrator, and a wire are provided. The case has a bottomed cylindrical shape, the case including a bottom portion and a side wall portion. The piezoelectric vibrator includes piezoelectric ceramic containing Ti and Zr, and is attached to the bottom portion inside the case. The wire is connected to the piezoelectric vibrator and extends to an outside of the case. A resonance frequency in a spreading vibration mode of the piezoelectric ceramic not attached to the bottom portion becomes minimum at a temperature in a range of about −30° C. or higher and about 10° C. or lower. A cross-sectional porosity in any longitudinal cross section of the piezoelectric ceramic is about 1% or less.

### CROSS REFERENCE TO RELATED APPLICATIONS

This application claims the benefit of priority to Japanese Patent Application No. 2021-193286, filed on Nov. 29, 2021, and is a Continuation application of PCT Application No. PCT/JP2022/037055, filed on Oct. 4, 2022. The entire contents of each application are hereby incorporated herein by reference.

### BACKGROUND OF THE INVENTION

### 1. Field of the Invention

The present invention relates to ultrasonic transducers and methods of manufacturing the same.

### 2. Description of the Related Art

Japanese Patent No. 2651140 is a prior art document disclosing a configuration of an ultrasonic transducer. The ultrasonic transducer disclosed in Japanese Patent No. 2651140 includes a piezoelectric vibrator, a ¼ wavelength acoustic matching layer, and a metal case. The piezoelectric vibrator utilizes a spreading vibration mode of a circular piezoelectric substrate.

Japanese Patent Laid-Open No. 2003-23187 is a prior art document disclosing a high heat-resistance piezoelectric element and a piezoelectric device produced using the same. In the high heat-resistance piezoelectric element disclosed in Japanese Patent Laid-Open No. 2003-23187, the resonance frequency of the piezoelectric resonance in a piezoelectric element before being heat-treated becomes minimum at a temperature in the range of 60° C. or higher and 200° C. or lower.

### SUMMARY OF THE INVENTION

The inventors of example embodiments of the present invention discovered that, for an ultrasonic transducer, its shortest detection distance at which a detection target can be detected should be about 20 cm or less.

Example embodiments of the present invention provide ultrasonic transducers and methods of manufacturing the same, by each of which a shortest detection distance at which a detection target can be detected is able to be set to about 20 cm or less.

An ultrasonic transducer according to an example embodiment of the present invention includes a case, a piezoelectric vibrator, and a wire. The case includes a bottomed cylindrical shape, and includes a bottom portion and a side wall portion. The piezoelectric vibrator includes a piezoelectric ceramic including Ti and Zr, the piezoelectric vibrator being attached to the bottom portion inside the case. The wire is connected to the piezoelectric vibrator and extends to an outside of the case. A resonance frequency in a spreading vibration mode of the piezoelectric ceramic not attached to the bottom portion reaches a smallest magnitude at a temperature in a range of about −30° C. or higher and about 10° C. or lower. A cross-sectional porosity in any longitudinal cross section of the piezoelectric ceramic is about 1% or less.

According to example embodiments of the present invention, a shortest detection distance at which a detection target can be detected is able to be set to about 20 cm or less.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a longitudinal cross-sectional view showing a configuration of an ultrasonic transducer according to an example embodiment of the present invention.

FIG. 2 is an SEM image of a longitudinal cross section of piezoelectric ceramic after being polished, according to Example 1 of the present invention.

FIG. 3 is an SEM image of a longitudinal cross section of piezoelectric ceramic after being polished, according to Comparative Example 3.

FIG. 4 is an SEM image of a longitudinal cross section of piezoelectric ceramic after being polished, according to Comparative Example 5.

FIG. 5 is a graph showing a relationship between an electromechanical coupling coefficient of the piezoelectric ceramic before being attached and an electromechanical coupling coefficient of the piezoelectric ceramic after being attached; and a temperature at which a resonance frequency of the piezoelectric ceramic becomes minimum, in the piezoelectric ceramic in each of Examples 1 to 5 of the present invention and Comparative Examples 1 to 3.

FIG. 6 is a diagram of a crystal state in a piezoelectric material according to an example embodiment of the present invention, which illustrates a relationship between a temperature at which the resonance frequency of the piezoelectric ceramic becomes minimum and a composition of the piezoelectric ceramic.

FIG. 7 is a flowchart illustrating a method of manufacturing the ultrasonic transducer according to an example embodiment of the present invention.

### DETAILED DESCRIPTION OF THE EXAMPLE EMBODIMENTS

The following describes ultrasonic transducers according to example embodiments of the present invention and methods of manufacturing the same with reference to the accompanying drawings. In the following description of the example embodiments, the same or corresponding portions in the drawings are denoted by the same reference characters, and the description thereof will not be repeated.

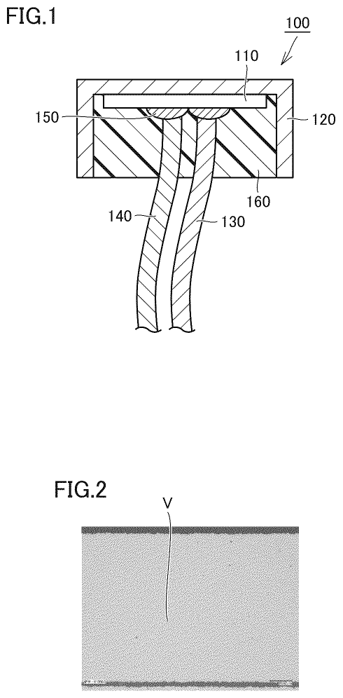

FIG. 1 is a longitudinal cross-sectional view showing a configuration of an ultrasonic transducer according to an example embodiment of the present invention. As shown in FIG. 1, an ultrasonic transducer 100 according to the present example embodiment of the present invention includes a case 120, a piezoelectric vibrator 110, a first wire 130, and a second wire 140. The ultrasonic transducer 100 further includes a bonding material 150 and a sealing material 160. Sealing material 160 is not necessarily provided and could be omitted if so desired.

Case 120 has a bottomed cylindrical shape and includes a bottom portion and a side wall portion. Case 120 is open at its upper end portion on the side opposite to the bottom portion. The bottom portion of case 120 preferably has, for example, a disk shape. The shape of the bottom portion of case 120 is not limited to a disk shape but may be, for example, a rectangular plate shape, a polygonal plate shape, or any other desirable shape. The side wall portion of case 120 is provided to rise from the peripheral edge of the bottom portion to extend in a direction vertical to the bottom portion. The case 120 is preferably made of aluminum, for example. The case 120 is electrically grounded.

Inside the case 120, the piezoelectric vibrator 110 is attached to the bottom portion of case 120 with an electrically insulating adhesive such as, for example, an epoxy resin. Piezoelectric vibrator 110 includes a plate-shaped piezoelectric ceramic. When viewed in a direction orthogonal or substantially orthogonal to the bottom portion of case 120, the piezoelectric ceramic has a square shape. The piezoelectric ceramic includes, for example, Ti and Zr. The piezoelectric ceramic is preferably made of, for example, lead zirconate titanate (PZT)-based ceramic. An electrode is provided on each of two main surfaces of the piezoelectric ceramic that oppose each other.

Each of first wire 130 and second wire 140 is connected to piezoelectric vibrator 110 and extends to the outside of case 120. Specifically, first wire 130 is electrically connected to the electrode on one main surface of the piezoelectric ceramic through bonding material 150 such as, for example, solder. Second wire 140 is electrically connected to the electrode on the other main surface of the piezoelectric ceramic through bonding material 150 such as, for example, solder. FIG. 1 shows the state in which second wire 140 is bonded with bonding material 150 to an extended electrode that is connected to the electrode on the other main surface of the piezoelectric ceramic and extends to the one main surface. In the present example embodiment, for example, the first wire 130 and the second wire 140 each are each preferably defined by lead wires, but may alternatively be provided by electrically conductive traces in a flexible printed circuit (an FPC).

When a drive voltage is applied between the electrodes on the piezoelectric ceramic through first wire 130 and second wire 140, piezoelectric vibrator 110 expands in the in-plane direction and vibrates. Vibration of piezoelectric vibrator 110 causes vibration of the bottom portion of case 120.

When the bottom portion of case 120 vibrates in response to ultrasonic waves received from the outside, piezoelectric vibrator 110 also vibrates in accordance with the vibration. When the vibration of piezoelectric vibrator 110 causes electric charge, the ultrasonic wave is converted into an electrical signal by piezoelectric vibrator 110. The electrical signal is transmitted to the outside from an electrode provided on the piezoelectric ceramic through first wire 130 and second wire 140.

The case 120 is filled with sealing material 160. Sealing material 160 fills the space inside case 120. Sealing material 160 is preferably, for example, made of rubber such as silicone rubber or urethane rubber, or made of a resin such as an epoxy resin, and has sound insulating properties and adhesiveness. A sound absorbing material made of a material with a lower modulus of elasticity than sealing material 160 may be located so as to cover piezoelectric vibrator 110. In this case, sealing material 160 covers the sound absorbing material.

### Experimental Example

The following describes an experimental example in which the correlation between the characteristics of the piezoelectric ceramic and the detection distance of the ultrasonic transducer has been verified. In the present experimental example, eleven types of ultrasonic transducers of Examples 1 to 5 and Comparative Examples 1 to 6 were prepared, and their characteristics were verified.

Table 1 summarizes the results of evaluating the characteristics of the piezoelectric ceramic and the ultrasonic transducer according to each of Examples 1 to 5 and Comparative Examples 1 to 6.

TABLE 1

| | | | | Temperature | Electromechanical | |
|---|---|---|---|---|---|---|
| | | | | at which | Coupling | |
| | | | | Resonance | Coefficient of | |
| | | | Cross- | Frequency | Attached | Shortest |
| | | | Sectional | Becomes | Piezoelectric | Detection |
| | Process | | Porosity | Minimum | Ceramic | Distance |
| | Method | Ti/Zr | (%) | (° C.) | (%) | (cm) |
| Example 1 | Sheet | 0.920 | 0.2 | 0 | 20.3 | 12 |
| | Molding | | | | | |
| Example 2 | Sheet | 0.935 | 1.0 | −30 | 18.7 | 17 |
| | Molding | | | | | |
| Example 3 | Sheet | 0.930 | 0.8 | −20 | 20.4 | 11 |
| | Molding | | | | | |
| Example 4 | Sheet | 0.925 | 0.7 | −10 | 20.7 | 10 |
| | Molding | | | | | |
| Example 5 | Sheet | 0.915 | 0.6 | 10 | 18.0 | 15 |
| | Molding | | | | | |
| Comparative | Sheet | 0.950 | 0.3 | −50 | 15.1 | 31 |
| Example 1 | Molding | | | | | |
| Comparative | Sheet | 0.900 | 0.5 | 30 | 14.6 | 32 |
| Example 2 | Molding | | | | | |
| Comparative | Sheet | 0.890 | 0.5 | 50 | 13.2 | 35 |
| Example 3 | Molding | | | | | |
| Comparative | Extrusion | 0.920 | 2.0 | 0 | 16.4 | 27 |
| Example 4 | Molding | | | | | |
| Comparative | Extrusion | 0.935 | 3.0 | −30 | 16.7 | 26 |
| Example 5 | Molding | | | | | |
| Comparative | Press | 0.920 | 6.0 | 0 | 13.3 | 35 |
| Example 6 | Molding | | | | | |

A lead zirconate titanate-based piezoelectric material used as a material of piezoelectric ceramic was produced by the following method. A prescribed amount of each of PbO powder, TiO₂ powder, ZrO₂ powder, water, a dispersant, and a medium for mixing and grinding was introduced into a container such that the content ratio of Ti to Zr was in the range of about 0.89 or more and about 0.95 or less. Then, the materials in the container were mixed and ground for about 24 hours. After mixing and grinding the materials, the resultant mixture was filtered to remove water, and dried at about 100° C. to obtain powder. The obtained powder was placed in a sheath made of Al₂O₃ and synthesized at a temperature of about 900° C. to about 1000° C. The synthesized powder was ground in a dry process, and then subjected to various process methods to prepare a piezoelectric material according to each of Examples 1 to 5 and Comparative Examples 1 to 6. The content ratios of Ti to Zr in the piezoelectric materials according to Examples 1 to 5 and Comparative Examples 1 to 6 are as shown in Table 1.

In each of Examples 1 to 5 and Comparative Examples 1 to 3, the piezoelectric material was sheet-molded. Specifically, a binder, a dispersant, and an antifoaming agent were added to the piezoelectric material to produce slurry. From this slurry, green sheets were produced with the use of a doctor blade method. The obtained green sheets were stacked and pressure-bonded to form a multilayer body, which was then fired to produce piezoelectric ceramic.

In each of Comparative Examples 4 and 5, a piezoelectric material was extrusion-molded. Specifically, a binder and a small amount of water were added to the piezoelectric material to produce a clayey piezoelectric material. Then, from this clayey piezoelectric material, a molded product was formed using an extruder, and this molded product was then fired to produce piezoelectric ceramic.

In Comparative Example 6, a piezoelectric material was press-molded. Specifically, a binder and a dispersant were added to dry powder of the piezoelectric material. Then, from this dry powder, a molded product was formed using a press molding machine, and this molded product was then fired to produce piezoelectric ceramic.

In each of Examples 1 to 5 and Comparative Examples 1 to 6, the obtained piezoelectric ceramic was processed to be formed in a rectangular parallelepiped shape having a one side length of about 5 mm and a thickness of about 0.2 mm. Then, an electrode made of Ag was formed by sputtering on each of both main surfaces of the piezoelectric ceramic, and then, a direct-current (DC) voltage was applied between these electrodes for polarization. After the polarized piezoelectric ceramic was attached to the bottom portion of case 120 with an adhesive, each of first wire 130 and second wire 140 was electrically connected by bonding material 150 to the electrode on the piezoelectric ceramic. After each of first wire 130 and second wire 140 was pulled out from case 120, case 120 was filled with a resin as sealing material 160 to produce an ultrasonic transducer according to each of Examples 1 to 5 and Comparative Examples 1 to 6.

Further, as a test piece used for obtaining the temperature at which the resonance frequency of the piezoelectric ceramic in each of Examples 1 to 5 and Comparative Examples 1 to 6 became minimum, a test piece was produced in the following way. Specifically, electrodes each made of Ag were formed by sputtering on both main surfaces of the piezoelectric ceramic produced under the same conditions as described above, and then, a DC voltage was applied between the electrodes for polarization to thereby produce a test piece having a long side length of about 4 mm, a short side length of about 1 mm, and a thickness of about 0.2 mm.

The ultrasonic transducer according to each of Examples 1 to 5 and Comparative Examples 1 to 6 was driven to evaluate the shortest detection distance. Further, the equivalent circuit constant in the main vibration mode of the ultrasonic transducer according to each of Examples 1 to 5 and Comparative Examples 1 to 6 was measured with the use of an impedance analyzer. Then, based on the square root of the value obtained by dividing the equivalent capacity by the damping capacity, the electromechanical coupling coefficient of the piezoelectric ceramic after being attached to the bottom portion of case 120 was calculated.

Further, the test piece of the piezoelectric ceramic according to each of Examples 1 to 5 and Comparative Examples 1 to 6 was introduced into a temperature bath, and the temperature was changed by 10-degree (about 10° C.) intervals within a range from about −50° C. to about 200° C., during which the resonance frequency in the spreading vibration mode (31 modes) of each test piece was obtained. Then, a temperature Tfm at which the resonance frequency became minimum was obtained.

Further, after the longitudinal cross section of the piezoelectric ceramic according to each of Examples 1 to 5 and Comparative Examples 1 to 6 was polished, each cross section was observed by a scanning electron microscope (SEM) to evaluate the cross-sectional porosity as the ratio of the area occupied by voids in the piezoelectric ceramic within a range of the field of view.

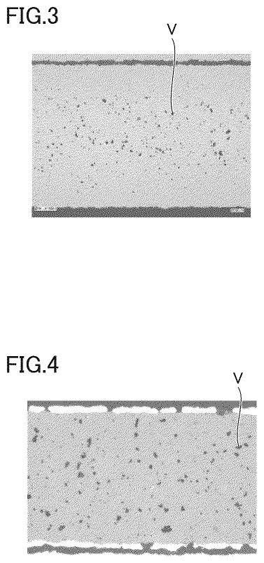

FIG. 2 is an SEM image of the longitudinal cross section of the piezoelectric ceramic after being polished, according to Example 1. FIG. 3 is an SEM image of the longitudinal cross section of the piezoelectric ceramic after being polished, according to Comparative Example 3. FIG. 4 is an SEM image of the longitudinal cross section of the piezoelectric ceramic after being polished, according to Comparative Example 5. In FIGS. 2 to 4, a black dot-like portion shows a void V. As shown in FIGS. 2 to 4, voids V were small in number in the piezoelectric ceramic according to Example 1 that was produced by sheet-molding a piezoelectric material; voids V were large in number in the piezoelectric ceramic according to Comparative Example 3 that was produced by extrusion-molding a piezoelectric material; and voids V were large in number and size in the piezoelectric ceramic according to Comparative Example 5 that was produced by press-molding a piezoelectric material.

As shown in Table 1, it was discovered that there was a strong correlation between the shortest detection distance of the ultrasonic transducer and the electromechanical coupling coefficient of the piezoelectric ceramic after being attached, and as the electromechanical coupling coefficient of the piezoelectric ceramic after being attached was higher, the shortest detection distance of the ultrasonic transducer could be shorter.

Thus, as a result of studies conducted for increasing the electromechanical coupling coefficient of the piezoelectric ceramic after being attached, it was discovered that the electromechanical coupling coefficient of the piezoelectric ceramic after being attached had a correlation between the electromechanical coupling coefficient of the piezoelectric ceramic before being attached and temperature Tfm at which the resonance frequency in the spreading vibration mode (31 modes) of the piezoelectric ceramic became minimum.

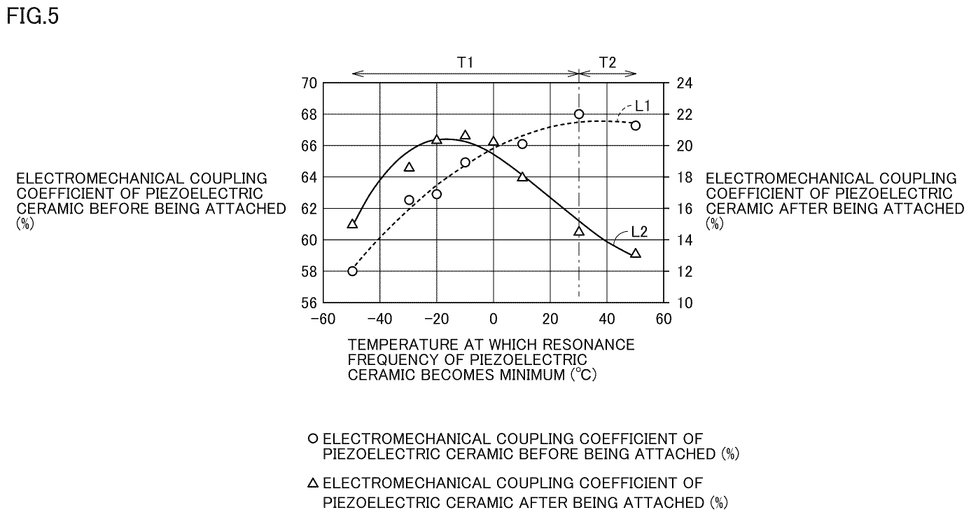

FIG. 5 is a graph showing the relationship between an electromechanical coupling coefficient of the piezoelectric ceramic before being attached and an electromechanical coupling coefficient of the piezoelectric ceramic after being attached, and a temperature at which the resonance frequency of the piezoelectric ceramic becomes minimum, in the piezoelectric ceramic in each of Examples 1 to 5 and Comparative Examples 1 to 3. In FIG. 5, the vertical axis on the left side represents the electromechanical coupling coefficient (%) of the piezoelectric ceramic before being attached, the vertical axis on the right side represents the electromechanical coupling coefficient (%) of the piezoelectric ceramic after being attached, and the horizontal axis represents the temperature (° C.) at which the resonance frequency of the piezoelectric ceramic becomes minimum. Further, circular marks each indicate the electromechanical coupling coefficient of the piezoelectric ceramic before being attached, and triangular marks each indicate the electromechanical coupling coefficient of the piezoelectric ceramic after being attached. Also, a dotted line L1 indicates an approximate curve of the transition of the electromechanical coupling coefficient of the piezoelectric ceramic before being attached, and a solid line L2 indicates an approximate curve of the transition of the electromechanical coupling coefficient of the piezoelectric ceramic after being attached.

As shown in FIG. 5, it was found that the electromechanical coupling coefficient of the piezoelectric ceramic before being attached and the electromechanical coupling coefficient of the piezoelectric ceramic after being attached are different from each other in terms of the transition with respect to the change in temperature Tfm at which the resonance frequency in the spreading vibration mode (31 modes) of the piezoelectric ceramic becomes minimum. Specifically, the electromechanical coupling coefficient of the piezoelectric ceramic before being attached and the electromechanical coupling coefficient of the piezoelectric ceramic after being attached were different from each other in terms of temperature Tfm at which these electromechanical coupling coefficients reached their respective peaks. Thus, temperature Tfm at which the electromechanical coupling coefficient of the piezoelectric ceramic before being attached becomes high is equal to a room temperature (about 30° C.), whereas temperature Tfm at which the electromechanical coupling coefficient of the piezoelectric ceramic after being attached becomes high is about −15° C. This showed that the composition of the piezoelectric ceramic by which the electromechanical coupling coefficient of the piezoelectric ceramic became maximum was different between before and after the piezoelectric ceramic was attached, as will be described later.

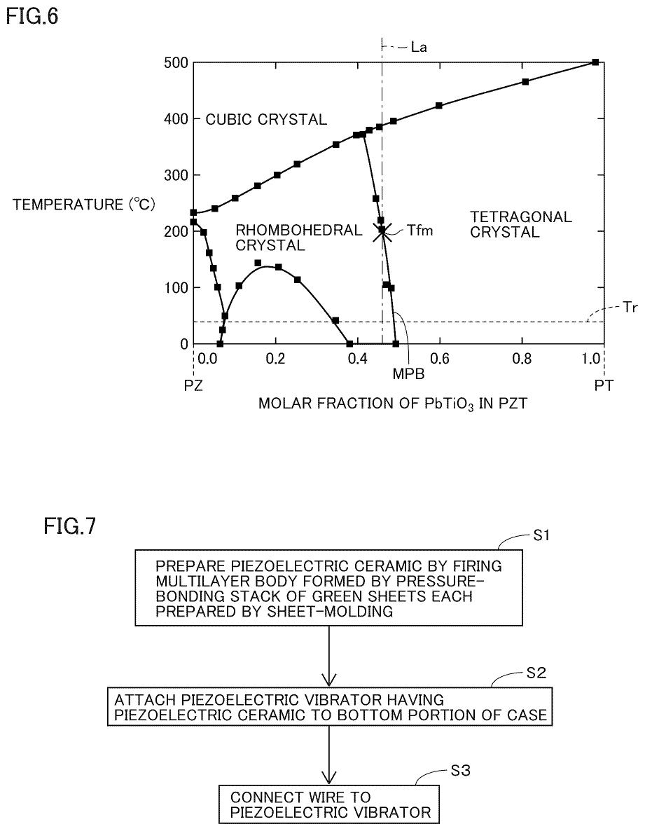

The following describes the relation between the composition of the piezoelectric ceramic and temperature Tfm at which the resonance frequency in the spreading vibration mode (31 modes) of the piezoelectric ceramic becomes minimum. FIG. 6 is a diagram of the crystal state in the piezoelectric material, which illustrates the relation between the temperature at which the resonance frequency of the piezoelectric ceramic becomes minimum and the composition of the piezoelectric ceramic. In FIG. 6, the vertical axis represents the temperature (° C.) and the horizontal axis represents the molar fraction of PbTiO₃ in PZT. A room temperature Tr is indicated by a dotted line. When the piezoelectric ceramic has a composition indicated by a dash-dotted line La, the temperature at the point of intersection between this dash-dotted line La and a morphotropic phase boundary MPB is equivalent to temperature Tfm at which the resonance frequency in the spreading vibration mode (31 modes) of the piezoelectric ceramic having the above-mentioned composition becomes minimum. This morphotropic phase boundary MPB is a phase boundary between a rhombohedral crystal and a tetragonal crystal. In other words, changing the content ratio of Ti to Zr in the piezoelectric material makes it possible to adjust temperature Tfm at which the resonance frequency in the spreading vibration mode (31 modes) of the piezoelectric ceramic becomes minimum.

As shown in FIG. 5, in a composition range T1 in which temperature Tfm at which the resonance frequency in the spreading vibration mode (31 modes) of the piezoelectric ceramic becomes minimum is lower than a room temperature indicated by the dash-dotted line, the crystal structure of the piezoelectric ceramic turns into a tetragonal crystal at a room temperature. Also, in a composition range T2 in which temperature Tfm is higher than a room temperature indicated by the dash-dotted line, the crystal structure of the piezoelectric ceramic turns into a rhombohedral crystal at a room temperature.

As shown in FIG. 5, in the piezoelectric ceramic in each of Examples 1 to 5 in which temperature Tfm at which the resonance frequency in the spreading vibration mode (31 modes) of the piezoelectric ceramic became minimum was in the range of about −30° C. or higher and about 10° C. or lower, the electromechanical coupling coefficient of the piezoelectric ceramic after being attached was kept as high as about 18% or more.

It is considered that this is due to the following reasons. Specifically, the electromechanical coupling coefficient of the piezoelectric ceramic itself decreases due to the stress applied to the piezoelectric ceramic when the piezoelectric ceramic is attached to case 120, but the piezoelectric ceramic is prepared to have a composition such that temperature Tfm falls within the range of about −30° C. or higher and about 10° C. or lower, and thereby, the piezoelectric ceramic has a stable tetragonal crystal structure at a room temperature, which makes it possible to reduce or prevent a decrease in the electromechanical coupling coefficient of the piezoelectric ceramic at the time when the piezoelectric ceramic is attached to case 120.

Conventionally, the composition of the piezoelectric ceramic has been determined such that the electromechanical coupling coefficient of the piezoelectric ceramic before being attached becomes maximum at a room temperature, i.e., such that temperature Tfm at which the resonance frequency in the spreading vibration mode (31 modes) of the piezoelectric ceramic becomes minimum is equal to a room temperature. In this case, as shown in FIG. 5, the electromechanical coupling coefficient of the piezoelectric ceramic after being attached decreases, so that the shortest detection distance of the ultrasonic transducer cannot be shortened.

As shown in Table 1, in each of the ultrasonic transducers according to Examples 1 to 5, the electromechanical coupling coefficient of the piezoelectric ceramic after being attached was kept as high as about 18% or more, with the result that the shortest detection distance of the ultrasonic transducer could be set to be about 20 cm or less. On the other hand, in each of Comparative Examples 1 to 3 in which temperature Tfm at which the resonance frequency in the spreading vibration mode (31 modes) of the piezoelectric ceramic became minimum was outside the range of about −30° C. or higher and about 10° C. or lower, the electromechanical coupling coefficient of the piezoelectric ceramic after being attached was less than 18%, with the result that the shortest detection distance of the ultrasonic transducer could not be set to be about 20 cm or less.

As shown in Table 1, in each of the ultrasonic transducers according to Comparative Examples 4 to 6, temperature Tfm at which the resonance frequency in the spreading vibration mode (31 modes) of the piezoelectric ceramic became minimum was in the range of about −30° C. or higher and about 10° C. or lower, but the electromechanical coupling coefficient of the piezoelectric ceramic after being attached was less than about 18%, with the result that the shortest detection distance of the ultrasonic transducer could not be set to be about 20 cm or less.

It is considered that this is because the cross-sectional porosity of the piezoelectric ceramic according to each of Comparative Examples 4 to 6 is greater than about 1%, which leads to a significant decrease in the electromechanical coupling coefficient of the piezoelectric ceramic at the time when the piezoelectric ceramic is attached to case 120.

In each of the ultrasonic transducers in Examples 1 to 5, the cross-sectional porosity of the piezoelectric ceramic was about 1% or less, which also made it possible to reduce or prevent a decrease in the electromechanical coupling coefficient of the piezoelectric ceramic at the time when the piezoelectric ceramic was attached to case 120. As a result, the electromechanical coupling coefficient of the piezoelectric ceramic after being attached was kept as high as about 18% or more, and thus, the shortest detection distance of the ultrasonic transducer could be set to be about 20 cm or less.

As can be seen from the above-described experimental results, in ultrasonic transducer 100 according to an example embodiment of the present invention, the resonance frequency in the spreading vibration mode (31 modes) of the piezoelectric ceramic not attached to the bottom portion of case 120 becomes minimum at temperature Tfm in the range of about −30° C. or higher and about 10° C. or lower. The cross-sectional porosity in any longitudinal cross section of the piezoelectric ceramic is about 1% or less. Thereby, the electromechanical coupling coefficient of the piezoelectric ceramic after being attached can be kept as high as about 18% or more, and thus, the shortest detection distance of ultrasonic transducer 100 can be set to be about 20 cm or less.

Preferably, the resonance frequency in the spreading vibration mode of the piezoelectric ceramic not attached to the bottom portion of case 120 becomes minimum at a temperature in the range of about −20° C. or higher and about 0° C. or lower. Thus, the electromechanical coupling coefficient of the piezoelectric ceramic after being attached can be kept as high as about 20% or more, and thus, the shortest detection distance of ultrasonic transducer 100 can be set to be about 12 cm or less.

Conventionally, piezoelectric ceramic manufactured by a low-cost process such as extrusion molding or press molding has been used for an ultrasonic transducer. However, the ultrasonic transducer according to the present example embodiment is manufactured by the following steps, and thus, the shortest detection distance can be set to be about 20 cm or less.

FIG. 7 is a flowchart illustrating a method of manufacturing the ultrasonic transducer according to one example embodiment of the present invention. As shown in FIG. 7 and Table 1, the method of manufacturing the ultrasonic transducer according to one example embodiment of the present invention includes: a step (S1) of preparing piezoelectric ceramic by firing a multilayer body formed by pressure-bonding a stack of a plurality of green sheets, each of the green sheets being prepared by sheet-molding a lead zirconate titanate-based material in which a content ratio of Ti to Zr is in a range of about 0.915 or more and about 0.935 or less; a step (S2) of attaching a piezoelectric vibrator having the piezoelectric ceramic to a bottom portion of a case having a bottomed cylindrical shape; and a step (S3) of connecting a wire to the piezoelectric vibrator.

In the above description of the present example embodiment, configurations that can be combined may be combined with each other.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An ultrasonic transducer comprising:
a case having a bottomed cylindrical shape, the case including a bottom portion and a side wall portion;
a piezoelectric vibrator including a piezoelectric ceramic including Ti and Zr, the piezoelectric vibrator being attached to the bottom portion inside the case; and
a wire connected to the piezoelectric vibrator and extending to an outside of the case; wherein
a resonance frequency in a spreading vibration mode of the piezoelectric ceramic not attached to the bottom portion reaches its smallest magnitude at a temperature in a range of about −30° C. or higher and about 10° C. or lower; and
a cross-sectional porosity in any longitudinal cross section of the piezoelectric ceramic is about 1% or less.

2. The ultrasonic transducer according to claim 1, wherein a resonance frequency in a spreading vibration mode of the piezoelectric ceramic not attached to the bottom portion reaches its smallest magnitude at a temperature in a range of about −20° C. or higher and about 0° C. or lower.

3. A method of manufacturing an ultrasonic transducer, the method comprising:
preparing piezoelectric ceramic by firing a multilayer body formed by pressure-bonding a stack of a plurality of green sheets, each of the plurality of green sheets being prepared by sheet-molding a lead zirconate titanate-based material in which a content ratio of Ti to Zr is in a range of about 0.915 or more and about 0.935 or less;
attaching a piezoelectric vibrator including the piezoelectric ceramic to a bottom portion of a case having a bottomed cylindrical shape; and
connecting a wire to the piezoelectric vibrator.

4. The ultrasonic transducer according to claim 1, wherein the bottom portion inside the case has a disk shape.

5. The ultrasonic transducer according to claim 1, wherein the bottom portion inside the case has a rectangular plate shape or a polygonal plate shape.

6. The ultrasonic transducer according to claim 1, wherein an electrically insulating material is used to attach the piezoelectric vibrator to the bottom portion inside the case.

7. The ultrasonic transducer according to claim 1, wherein
when viewed in a direction orthogonal to the bottom portion of case, the piezoelectric ceramic has a square shape; and
the piezoelectric ceramic contains Ti and Zr.

8. The ultrasonic transducer according to claim 7, wherein an electrode is provided on each of two main surfaces of the piezoelectric ceramic that oppose each other.

9. The ultrasonic transducer according to claim 1, further comprising an additional wire connected to the piezoelectric vibrator and extending to the outside of the case.

10. The ultrasonic transducer according to claim 1, wherein the case is filled with a sealing material.

11. The ultrasonic transducer according to claim 10, wherein the sealing material has sound insulating properties and adhesiveness.
